(19) United States
(12) Patent Application Publication
(10) Pub. No.: US 2008/0224897 A1
(43) Pub. Date: Sep. 18, 2008

(54) Computer keypad for improved input efficiency

(76) Inventor: David P. Silva, Flanders, NJ (US)

Correspondence Address: Russ Weinzimmer, 614 Nashua St. #204, Milford, NH, 03055, US

(21) Appl. No.: 11/717,916

(22) Filed: Mar. 14, 2007

(51) Int. Cl. H03M 11/00

(52) U.S. Cl. 341/22

(57) ABSTRACT

A numeric key pad is provided for efficiently entering numbers and symbols into a computer. The numeric key pad includes a number region having digits 1-9 arranged in a 3×3 grid, the 3×3 grid having N, S, E, W, NE, SE, NW, SW, and Central positions. The numeric keypad also includes a nearest neighbor symbol region having a first plurality of symbols, each symbol being at a nearest neighbor position of the 3×3 grid, the first plurality of symbols being selected from the set including: esc, $, Tab, Backspace, =, comma, #, %, [symbol] , [symbol] , (, ), space. The numeric keypad includes all of the standard keys, along with non-standard yet often-used keys. The non-standard keys are located with the standard keys such that they all fall within the natural finger extension range of a user. The numeric key pad can also be advantageously incorporated into an alphanumeric keyboard.

### FIELD OF THE INVENTION

The present invention relates to computer keyboards and keypads, and particularly to a computer keyboard or keypad having various features that improve efficiency as well as convenience when entering commands and data into an electronic spreadsheet or other financial software program.

### BACKGROUND OF THE INVENTION

Electronic keyboards for use with computing devices typically include many individual keys, and the keys are very commonly found in standard groups, each group being intended for particular purposes. For example, computer keyboards typically have a group of alphanumeric keys arranged in a predefined configuration, such as that used in conventional QWERTY configurations, for enabling a user to input text into the computer. Computer keyboards also typically include a numeric keypad, which includes a group of numeric keys and functions that are set apart from the alphanumeric keys, for enabling the user to more conveniently enter numbers with one hand, such as when using accounting software. A number of other key groups include editing keys (e.g., delete, insert, home, end, page up, page down, etc.), navigation keys (e.g., cursor controlling arrow keys), action keys (e.g., escape, print screen, scroll lock, etc.), and programmable function keys (e.g., F1-F12).

The QWERTY key layout has remained largely unchanged for 130 years. Further, the numeric keypad has seen little modification since its development in the early days of computing. This is notable because the common applications which require intensive numeric entry have changed markedly over the years. There has arisen a de facto standard spreadsheet application in the computing world—Microsoft Excel®. Input of numeric data into Microsoft Excel® requires the use of the various keys all over the computer keyboard. This sometimes requires the use of both hands.

Users of Microsoft Excel® sometimes must perform, in addition to alpha and numeric input, the creation of both simple and highly complex formulae that involve mathematical operations, such as addition, subtraction, division, multiplication, as well as special characters, such as the dollar sign ($). These formulae are input into data input fields, known as cells, within the spreadsheet. However, the keys necessary to input the commands driving these formulae are not found on or near the keypad, but are spread throughout the QWERTY section of the keyboard.

One software company, ZePocketForge, has recognized this problem and attempted to alleviate it with a software solution—displaying the keypad with necessary formula keys on the screen of a PocketPC. This is certainly an improvement for the users of the PocketPC who normally input via stylus, but has no application for personal computer users, as the input speed with a mouse is markedly slower than typing.

On a standard keyboard of today, typing many of these commands requires a one-way movement of the right hand in excess of 12-14 inches, and a round-trip movement of 24-28 inches. This greatly slows down the rate of data entry, due to the excessive movement involved, the search for the desired key, and the interruption in the thought process.

Companies hiring numeric data entry operators expect at least 10,000 ksph (key strokes per hour). Such data entry operators are responsible for keying information into various systems, and must exercise great care and an eye for detail, and be committed to producing accurate results. Yet, most data entry operators use standard keyboards/keypads, which, as noted above, are not optimized for their application, regarding either efficiency or convenience during data entry.

Also, of great interest to the intensive user of accounting and/or financial software is a simple calculator. Yet, many users often experience that the calculator, which is a device entirely separate from the computer or it's keyboard, is temporarily lost.

### SUMMARY OF THE INVENTION

The computer keypad and keyboard of the invention provides enhanced data input efficiency when used with computer programs that require numeric or formulaic entry, such as Microsoft Excel®. The computer keypad includes all of the standard keys found in known computer keypads, along with non-standard yet essential and often-used keys that are not included in standard keypads. The non-standard keys are intermixed with the standard keys such that the new collection of keys places an augmented set of keys within the natural finger extension range of the typical user. Consequently, data and formula input efficiency is greatly improved.

The invention provides great advantage in efficiency to many professionals such as accountants, data entry operators, mathematicians, and auditors. In some preferred embodiments, using a switch, the keypad becomes the input device for a calculator embedded within the keyboard that includes the keypad. The keyboard also includes a numeric display near the keypad, the display being for showing input data, and output results provided by the calculator. Including a calculator processor integrated with the keypad provides the convenience of always having a calculator at hand when working with the keypad of the invention.

Because professional users of electronic spreadsheets and financial software programs often use a calculator while preparing for or checking data entry, the invention provides advantage over prior art through the integration of a calculator function and display into a keyboard. By enabling the calculator function of the invention, a user can utilize the keypad numbers and standard operators (+, −, *, and /) to verify data easily without having to search for a handheld calculator or obstruct an area of the computer display screen with an onscreen calculator. Therefore the invention provides the advantage of allowing a user, through single-hand operation, to perform both data entry and checking activity.

The computer keypad of the invention improves upon existing keyboard and keypad technology commonly used with personal computers throughout the world. The computer keypad of the invention can be included in any otherwise standard keyboard, replacing the standard keypad, thereby providing an enhanced keyboard that is substantially improved for use with many electronic spreadsheet, mathematic, or financial software programs.

The invention includes keys typically found far from the numeric keypad of a standard keyboard, and includes a second version of select keys in the keypad of the invention. For example, the “=” key is normally found in the top row of a standard keyboard that also includes the numbers 1, 2, 3 . . . 9, and 0. However, according to the invention, a second “=” key is included, located in the keypad so as to improve input efficiency in programs such as Microsoft Excel®. By locating the “=” key within the keypad of the invention, the invention allows a user to easily and efficiently create numeric functions, without repeatedly moving their hand to the section of a standard keyboard containing the “=” key, and then back to the numbers of the numeric keypad.

For financial data entry and manipulation, the “$” key is often used. In known keyboards, such as the QWERTY keyboard, this key is only accessible through a two-handed operation involving both the “SHIFT” key and the “$” key. By locating a “$” key within the keypad of the invention, the invention provides a substantial advantages over the prior art because only one hand is required, and that hand is already in position to depress the “$” key, since the numbers, and other useful keys, are all included in the keypad.

A general aspect of the invention is a numeric key pad for entering numbers and symbols into a data processor. The numeric keypad includes: a number region having keys bearing digits 1-9 arranged in a 3×3 grid, the 3×3 grid having a N, S, E, W, NE, SE, NW, SW, and Central positions; and a nearest neighbor symbol region having keys bearing a first plurality of symbols, each symbol being on a key at a nearest neighbor position of a position of the 3×3 grid, the first plurality of symbols including symbols selected from the set including: esc, $, Tab, Backspace, =, comma, #, %, [symbol] , [symbol] , (, ), space.

In a preferred embodiment, the nearest neighbor symbol region further includes keys bearing symbols selected from the set including: numlock, /, *, +, −, enter, period.

In another preferred embodiment, an = key is above the NW position, a comma key is right of the NE position, the period key is right of the E position; and the ( key is right of the SE position.

In some preferred embodiments, the numeric keypad further includes a second nearest neighbor symbol region having keys bearing a second plurality of symbols, each symbol being on a key at a second nearest neighbor position of a position of the 3×3 grid, the second plurality including: esc, numlock, $, #, [symbol] ,).

In further preferred embodiments, the esc key is above the NW position; the numlock key is above the N position; the $ key is above the NE position; the # key is right of the NE position; the [symbol] key is right of the E position; and the ) key is right of the SE position.

In preferred embodiments, the numeric keypad further includes a third nearest neighbor symbol region having keys bearing a third plurality of symbols, each symbol being on a key at a third nearest neighbor position of the 3×3 grid, the third plurality including: Tab, +, %, [symbol] , Enter, and Backspace.

In further preferred embodiments, the % key is right of the NE position; the [symbol] key is right of the E position; the Enter key is right of the SE position; the Tab key is right of a second nearest neighbor of the NE position; and the Backspace key is a nearest neighbor of the Tab key.

In other preferred embodiments, the numeric keypad further includes a zero key below the SW and S positions.

In still other preferred embodiments, the numeric key pad further includes a space key at least below the SE position.

In yet other preferred embodiments, the numeric keypad includes a USB connector capable of connecting the numeric key pad to a laptop computer.

In preferred embodiments, the numeric key pad of claim 1 includes a display being capable of displaying at least the digits 1-9. In further preferred embodiments, the numeric keypad includes a calculator display switch capable of activating a calculator processor cooperative with the numeric keypad, results of calculations of the calculator processor being displayed on the display.

In other preferred embodiments, the numeric key pad is incorporated into a computer keyboard. In further embodiments, the computer keyboard includes a display being capable of displaying at least the digits 1-9, and a calculator display switch capable of activating a calculator processor cooperative with the numeric keypad, results of calculations of the calculator processor being displayed on the display.

Another general aspect of the invention is a computer keyboard having a numeric key pad for entering numbers and symbols into a data processor. The computer keyboard includes: a QWERTY keyboard for entering alphanumeric characters; and

a numeric keypad having a number region having keys bearing digits 1-9 arranged in a 3×3 grid, the 3×3 grid having a N, S, E, W, NE, SE, NW, SW, and Central positions, and a nearest neighbor symbol region having keys bearing a first plurality of symbols, each symbol being on a key at a nearest neighbor position of a position of the 3×3 grid, some of the first plurality of symbols being selected from the set including: esc, $, Tab, Backspace, =, comma, #, %, [symbol] , [symbol] , (, ), space.

In preferred embodiments, the nearest neighbor symbol region of the numeric keypad further includes keys bearing symbols selected from the set including: numlock, /, *, +, −, enter, period.

In further preferred embodiments, the numeric keypad includes a second nearest neighbor symbol region having keys bearing a second plurality of symbols, each symbol being on a key at a second nearest neighbor position of a position of the 3×3 grid, the second plurality including: esc, numlock, $, #, [symbol] ,).

In still further preferred embodiments, the numeric keypad includes a third nearest neighbor symbol region having keys bearing a third plurality of symbols, each symbol being on a key at a third nearest neighbor position of the 3×3 grid, the third plurality including: Tab, +, %, [symbol] , Enter, and Backspace.

In preferred embodiments, the computer keyboard includes a display being capable of displaying at least the digits 1-9. In further preferred embodiments, the computer keyboard includes a calculator display switch capable of activating a calculator processor cooperative with the numeric keypad, results of calculations of the calculator processor being displayed on the display.

### BRIEF DESCRIPTION OF THE DRAWING

The invention will be more fully understood by reference to the detailed description, in conjunction with the following figures, wherein:

FIG. 1 is a top plan view of a conventional known QWERTY keyboard with essential and often-used keys identified;

FIG. 2. is a top plan view of a preferred embodiment of the keypad of the invention showing a nearby calculator display above the keypad;

FIG. 3 is a keypad of FIG. 2 integrated with a conventional QWERTY keyboard; and

FIG. 4 is an alternate embodiment of the keypad of FIG. 2, presented as a mirrored key arrangement for left-handed users.

### DETAILED DESCRIPTION

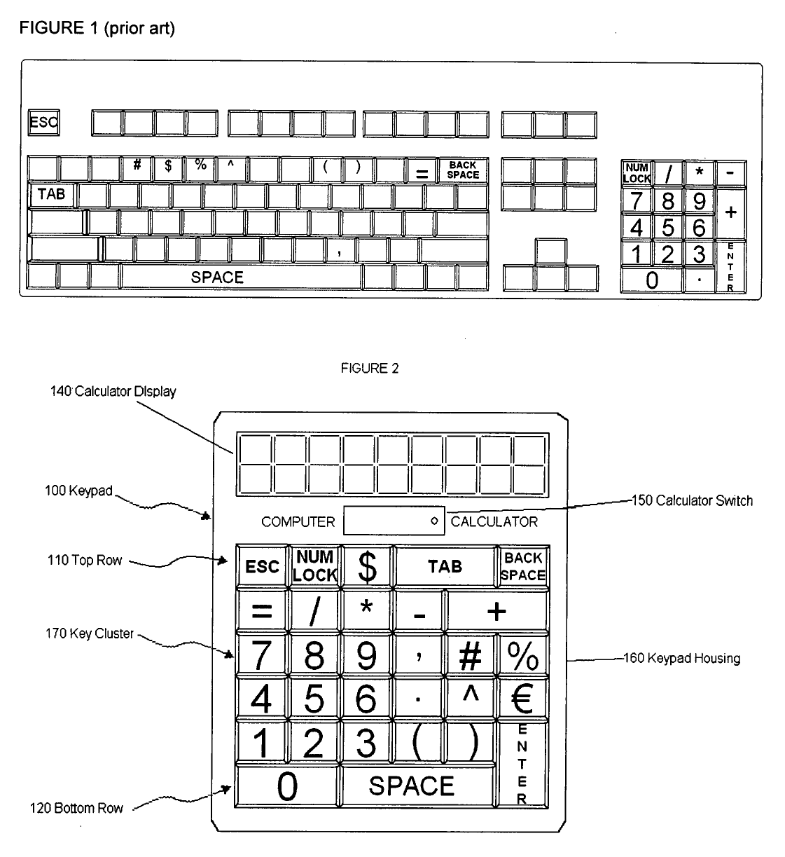

FIG. 1 shows a plan view of a conventional QWERTY keyboard commonly supplied with personal computers. Keys that are essential, or often-used keys for electronic spreadsheet, mathematical or financial software program data entry, are labeled with their common labels to illustrate their typical locations. These keys have specific functions or data values that are often used in the de facto standard spreadsheet application Microsoft Excel®.

FIG. 2 shows a plan view of a preferred embodiment of the invention which includes a key cluster 170 of thirty adjacent keys arranged in six rows, a calculator switch 150, a calculator display 140, and a keypad housing 160. The highlighted keys of FIG. 1 are grouped into a single key cluster 170 of adjacent keys such that all keys of the invention are within the natural finger extension range of the common user.

Key cluster 170 has a top row 110 of keys in sequence left to right of ESC, NUM LOCK, $, TAB, BACK SPACE. A row below and adjacent to top row 110 shows a sequence of keys left to right of =, /, *, −, +. The next lower adjacent row shows in sequence from left to right keys 7, 8, 9, ,, #, %. The next lower adjacent row shows in sequence from left to right keys 4, 5, 6, ., ̂, [symbol] . The next lower adjacent row shows in sequence from left to right keys 1, 2, 3, (, ), ENTER. The next lower adjacent row is bottom row 120 which shows in sequence from left to right keys 0, SPACE, ENTER.

The preferred embodiment of the invention of FIG. 2 also shows a calculator display 140 and a calculator switch 150. The calculator switch 150 is a toggle type switch connected to a calculator chip within the keypad housing. Calculator switch 150 enables the calculator chip to perform calculator functions, and to display key entry and calculator results on calculator display 140, while preventing all key cluster 170 entry from being communicated to a computer (not shown) connected to the keyboard that includes the keypad housing 160. In a preferred embodiment of the invention, calculator display 140 is constructed of light emitting diode (LED) elements. Alternatively, calculator display 140 could be constructed from liquid crystal display (LCD) or electroluminescent (EL) display technology commonly used in desktop calculators and digital clocks.

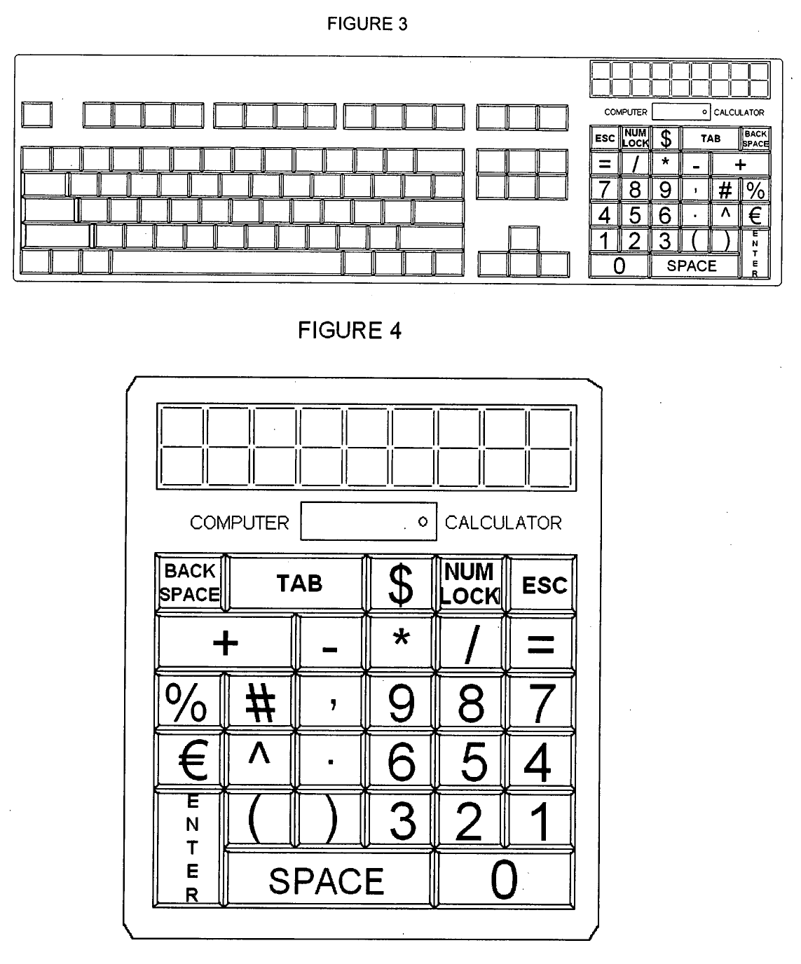

In the preferred embodiment of the invention in FIG. 2, key cluster 170, calculator display 140, and calculator switch 150 are assembled into keypad housing 160. However, the parts of the invention could be incorporated into a housing that also includes other key clusters such as those defined in International Standard ISO/IEC 9995 parts 2, 3, 5, or 6 to form a keyboard shown in FIG. 3. Alternatively calculator display 140 and/or calculator switch 150 could be housed or integrated separately from key cluster 170, such as to the side, or diagonally above the key cluster 170, as shown in FIG. 5 (as in the figure you provided me—to be included in final draft).

In a preferred embodiment of the invention, keypad 100 meets ergonomic and interface requirements of International Standard ISO/IEC 9995 enabling it to communicate with a compatible computer. However the keys of key cluster 170 may communicate information to a computer in any known arrangement. Additionally, the means of communication may include means other than those in ISO/IEC 9995 such as through a computer USB communication port, an infrared communication port, or other wireless communication port.

Alternative to the ergonomics of ISO/IEC 9995, the keys in key cluster 170 could be larger to accommodate users wearing gloves or smaller to meet space constraints of the application of the invention. The keys in key cluster 170 may provide some, little, or no tactile feedback. They may be mechanically, electrically, or magnetically actuated. They may be represented on a touch sensitive display screen such as that found in a handheld computing device.

The individual keys in key cluster 170 connect to and signal the CPU to communicate codes to a computer. When keypad 110 is communicating to a computer running the spreadsheet program Microsoft Excel®, certain keys in key cluster 170 provide essential functions. The Equal sign “=” key is necessary to entering formulae, the TAB key selects the next cell, the BACKSPACE key erases a mistaken entry, the ESC key erases the content of a highlighted cell, the ENTER key completes entry in a cell, and the parentheses “(” and “)” keys permit nested formulae. Keys such as the dollar sign “$”, euro “ [symbol] ”, and percent “%” define the format of data in a selected cell. The remaining keys in key cluster 170 communicate formula, mathematical operation, and number data.

The number of rows in key cluster 170, the number of keys per row, and the ordering of keys within rows may be alternatively arranged for a left-handed user. FIG. 4 shows a mirrored arrangement that may be suitable for a left-handed user.

The numeric keypad of the invention can be a separate device that includes a USB connector for enabling its connection and use with laptop computers, notebook computers, or any mobile computer with a keyboard lacking a numeric keypad and having a USB port. Of course, any connection means that serve to connect the numeric keypad with a mobile computer can be substituted for the USB connector, such as an infrared link, or a BlueTooth connection.

Attaching a numeric keypad facilitates data entry, resulting in increased efficiency.

Other modifications and implementations will occur to those skilled in the art without departing from the spirit and the scope of the invention as claimed. Accordingly, the above description is not intended to limit the invention except as indicated in the following claims.

What is claimed is:

1. A numeric key pad for entering numbers and symbols into a data processor, the numeric keypad comprising:
a number region having keys bearing digits 1-9 arranged in a 3×3 grid, the 3×3 grid having a N, S, E, W, NE, SE, NW, SW, and Central positions; and
a nearest neighbor symbol region having keys bearing a first plurality of symbols, each symbol being on a key at a nearest neighbor position of a position of the 3×3 grid, the first plurality of symbols including symbols selected from the set including:
esc, $, Tab, Backspace, =, comma, #, %, [symbol] , [symbol] , (, ), space.

2. The numeric key pad of claim 1, wherein the nearest neighbor symbol region further includes keys bearing symbols selected from the set including:
numlock, /, *, +, −, enter, period.

3. The numeric key pad of claim 2, wherein:
an = key is above the NW position;
a comma key is right of the NE position;
the period key is right of the E position; and
the ( key is right of the SE position.

4. The numeric key pad of claim 1, further comprising:
a second nearest neighbor symbol region having keys bearing a second plurality of symbols, each symbol being on a key at a second nearest neighbor position of a position of the 3×3 grid, the second plurality including:
esc, numlock, $, #, [symbol] , )

5. The numeric keypad of claim 4, wherein:
the esc key is above the NW position;
the numlock key is above the N position;
the $ key is above the NE position;
the # key is right of the NE position;
the [symbol] key is right of the E position; and
the ) key is right of the SE position.

6. The numeric key pad of claim 4, further comprising:
a third nearest neighbor symbol region having keys bearing a third plurality of symbols, each symbol being on a key at a third nearest neighbor position of the 3×3 grid, the third plurality including:
Tab, +, %, [symbol] , Enter, and Backspace

7. The numeric key pad of claim 6, wherein:
the % key is right of the NE position;
the [symbol] key is right of the E position;
the Enter key is right of the SE position;
the Tab key is right of a second nearest neighbor of the NE position; and
the Backspace key is a nearest neighbor of the Tab key.

8. The numeric key pad of claim 1, further comprising:
a zero key below the SW and S positions.

9. The numeric key pad of claim 1, further comprising:
a space key at least below the SE position.

10. The numeric key pad of claim 1, further comprising:
a USB connector capable of connecting the numeric key pad to a laptop computer.

11. The numeric key pad of claim 1, further comprising:
a display being capable of displaying at least the digits 1-9.

12. The numeric key pad of claim 11, further comprising:
a calculator display switch capable of activating a calculator processor cooperative with the numeric keypad, results of calculations of the calculator processor being displayed on the display.

13. The numeric key pad of claim 1, wherein the numeric key pad is incorporated into a computer keyboard.

14. The numeric keypad of claim 13, the computer keyboard further including:
a display being capable of displaying at least the digits 1-9; and
a calculator display switch capable of activating a calculator processor cooperative with the numeric keypad, results of calculations of the calculator processor being displayed on the display.

15. A computer keyboard having a numeric key pad for entering numbers and symbols into a data processor, the computer keyboard comprising:
a QWERTY keyboard for entering alphanumeric characters; and
a numeric keypad having a number region having keys bearing digits 1-9 arranged in a 3×3 grid, the 3×3 grid having a N, S, E, W, NE, SE, NW, SW, and Central positions, and a nearest neighbor symbol region having keys bearing a first plurality of symbols, each symbol being on a key at a nearest neighbor position of a position of the 3×3 grid, some of the first plurality of symbols being selected from the set including:
esc, $, Tab, Backspace, =, comma, #, %, [symbol] , [symbol] , (, ), space.

16. The computer keyboard of claim 15, wherein the nearest neighbor symbol region of the numeric keypad further includes keys bearing symbols selected from the set including:
numlock, /, *, +, −, enter, period.

17. The computer keyboard of claim 15, the numeric keypad further comprising:
a second nearest neighbor symbol region having keys bearing a second plurality of symbols, each symbol being on a key at a second nearest neighbor position of a position of the 3×3 grid, the second plurality including:
esc, numlock, $, #, [symbol] , )

18. The computer keyboard of claim 17, the numeric keypad further comprising:
a third nearest neighbor symbol region having keys bearing a third plurality of symbols, each symbol being on a key at a third nearest neighbor position of the 3×3 grid, the third plurality including:
Tab, +, %, [symbol] , Enter, and Backspace

19. The computer keyboard of claim 15, further comprising:
a display being capable of displaying at least the digits 1-9.

20. The computer keyboard of claim 19, further comprising:
a calculator display switch capable of activating a calculator processor cooperative with the numeric keypad, results of calculations of the calculator processor being displayed on the display.
